(19) United States
(12) Patent Application Publication
(10) Pub. No.: US 2015/0340427 A1
(43) Pub. Date: Nov. 26, 2015

(54) CAPACITOR STRUCTURE AND METHOD OF MANUFACTURING THE SAME

(71) Applicant: Powerchip Technology Corporation, Hsinchu (TW)

(72) Inventors: Yukihiro Nagai, Hsinchu City (TW); Hui-Huang Chen, Changhua County (TW); Ching-Hua Chen, Hsinchu City (TW); Ying-Chia Lin, Hsinchu City (TW)

(21) Appl. No.: 14/497,345

(22) Filed: Sep. 26, 2014

(30) Foreign Application Priority Data
May 23, 2014 (TW) 103118065

(51) Int. Cl. H01L 49/02

(52) U.S. Cl. CPC H01L 28/75

(57) ABSTRACT

A capacitor structure including at least one capacitor unit is provided. The capacitor unit includes a dielectric layer, an inner metal layer and an outer metal layer. The inner metal layer is disposed in the dielectric layer. The outer metal layer is disposed in the dielectric layer and surrounds the inner metal layer. The outer metal layer includes a first metal layer, two second metal layers and a third metal layer. The first metal layer is disposed under the inner metal layer. The second metal layers are disposed at two sides of the inner metal layer, and lower surfaces of the second metal layers are located equal to or below a lower surface of the inner metal layer. The third metal layer is disposed over the inner metal layer and connects to the second metal layers.

### CROSS-REFERENCE TO RELATED APPLICATION

This application claims the priority benefit of Taiwan application serial no. 103118065, filed on May 23, 2014. The entirety of the above-mentioned patent application is hereby incorporated by reference herein and made a part of this specification.

### BACKGROUND OF THE INVENTION

1. Field of the Invention

The invention relates to a capacitor structure and a method of manufacturing the same, and more particularly, relates to a capacitor structure having high capacitance and a method of manufacturing the same.

2. Description of Related Art

In current semiconductor industry, a capacitor is a very important basic component. For instance, a metal-oxide-metal capacitor (MOM capacitor) is a common capacitor structure. A basic design of the MOM capacitor includes filling a dielectric material between metal plates served as electrodes, so that one capacitor unit may be formed by two adjacent metal plates and the dielectric material located between the two adjacent plates.

However, with the demands of miniaturization for semiconductor, an integration of integrated circuit is increasingly higher. How to improve the capacitor structure based on specifications in the existing process in order to increase capacitance has become an important research topic.

### SUMMARY OF THE INVENTION

The invention provides a capacitor structure, which has higher capacitance.

The invention provides a method of manufacturing a capacitor structure, which can be easily integrated into the existing process.

The invention proposes a capacitor structure, which includes at least one capacitor unit. The capacitor unit includes a dielectric layer, an inner metal layer and an outer metal layer. The inner metal layer is disposed in the dielectric layer. The outer metal layer is disposed in the dielectric layer and surrounds the inner metal layer. The outer metal layer includes a first metal layer, two second metal layers and a third metal layer. The first metal layer is disposed under the inner metal layer. The second metal layers are disposed at two sides of the inner metal layer, and lower surfaces of the second metal layers are located equal to or below a lower surface of the inner metal layer. The third metal layer is disposed over the inner metal layer and connects to the second metal layers.

According to an embodiment of the invention, in said capacitor structure, the second metal layers may not be connected to the first metal layer.

According to an embodiment of the invention, in said capacitor structure, the second metal layers may be connected to the first metal layer.

According to an embodiment of the invention, in said capacitor structure, the first metal layers, the second metal layers, and the third metal layers may be electrically connected to one another.

According to an embodiment of the invention, in said capacitor structure, when a number of the capacitor unit is plural, the first metal layers, the second metal layers, and the third metal layers may be electrically connected to one another, and the inner metal layers may be electrically connected to one another.

According to an embodiment of the invention, in said capacitor structure, when a number of the capacitor unit is plural, two horizontally-adjacent capacitor units may collectively use the second metal layer located therebetween and collectively use the first metal layer and the third metal layer, and among vertically-adjacent capacitor units, the third metal layer of the capacitor unit at below may be the first metal layer of the capacitor unit at above.

According to an embodiment of the invention, in said capacitor structure, at least one opening may be included in the first metal layer.

According to an embodiment of the invention, in said capacitor structure, at least one opening may be included in the third metal layer.

According to an embodiment of the invention, said capacitor structure further includes a first etching stop layer, which is disposed between the first metal layer and the inner metal layer.

According to an embodiment of the invention, said capacitor structure further includes a second etching stop layer, which is disposed between the inner metal layer and the third metal layer.

The invention proposes a method of manufacturing a capacitor structure, which includes the following steps. A first dielectric layer is formed on a substrate. A first metal layer is formed in the first dielectric layer. A second dielectric layer is formed on the first dielectric layer. At least one inner metal layer is formed in the second dielectric layer. A third dielectric layer is formed on the second dielectric layer. A metal structure is formed in the third dielectric layer and the second dielectric layer, and the metal structure includes a plurality of second metal layers and a third metal layer. The second metal layers are disposed at two sides of the inner metal layer, and lower surfaces of the second metal layers are located equal to or below a lower surface of the inner metal layer. The third metal layer is disposed over the inner metal layer and connects to the second metal layers.

According to an embodiment of the invention, in the method of manufacturing said capacitor structure, a method of forming the metal structure is, for example, a dual damascene method.

According to an embodiment of the invention, in the method of manufacturing said capacitor structure, a method of forming the metal structure include the following steps. An opening structure is formed in the third dielectric layer and the second dielectric layer, and the opening structure includes first openings and a second opening. The first openings are disposed at two sides of the inner metal layer, and bottom portions of the first openings are located equal to or below the lower surface of the inner metal layer. The second opening is disposed over the at least one inner metal layer, and connects to the first openings. A metal material layer filling the opening structure is formed. The metal material layer located outside the opening structure is removed.

According to an embodiment of the invention, in the method of manufacturing said capacitor structure, the second metal layers may not be connected to the first metal layer.

According to an embodiment of the invention, in the method of manufacturing said capacitor structure, the second metal layers may be connected to the first metal layer.

According to an embodiment of the invention, the method of manufacturing said capacitor structure further includes forming at least one opening in the first metal layer.

According to an embodiment of the invention, the method of manufacturing said capacitor structure further includes forming at least one opening in the third metal layer.

According to an embodiment of the invention, the method of manufacturing said capacitor structure further includes forming a first etching stop layer between the first dielectric layer and the second dielectric layer.

According to an embodiment of the invention, the method of manufacturing said capacitor structure further includes forming a second etching stop layer between the second dielectric layer and the third dielectric layer.

According to an embodiment of the invention, the method of manufacturing said capacitor structure further includes repeatedly performing the steps of forming the second dielectric layer, the inner metal layer, the third dielectric layer and the metal structure, so as to form a stack type capacitor structure.

Based on above, because the outer metal layer surrounds the inner metal layer in the capacitor structure proposed by the invention, higher capacitance may be provided. In addition, because the method of manufacturing the capacitor structure proposed by the invention can be easily integrated into the existing process, the capacitor structure can be easily manufactured without increasing complexity of the process.

To make the above features and advantages of the disclosure more comprehensible, several embodiments accompanied with drawings are described in detail as follows.

### BRIEF DESCRIPTION OF THE DRAWINGS

FIG. 1A to FIG. 1E are cross-sectional views of a manufacturing process of a capacitor structure according to an embodiment of the invention.

FIG. 2 is a three dimensional view of the metal layers in the capacitor structure of FIG. 1E.

FIG. 3 is a cross-sectional view of a capacitor structure according to another embodiment of the invention.

FIG. 4 is a cross-sectional view of a capacitor structure according to another embodiment of the invention.

### DESCRIPTION OF THE EMBODIMENTS

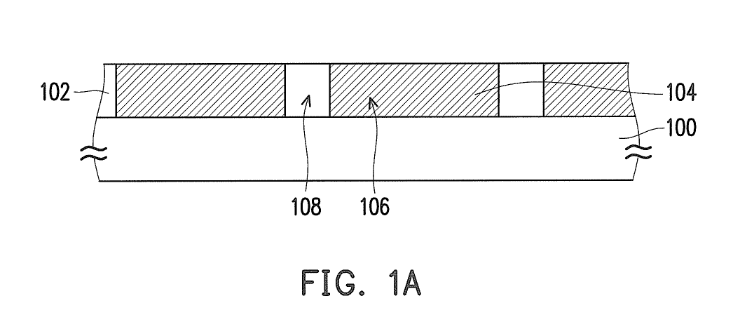

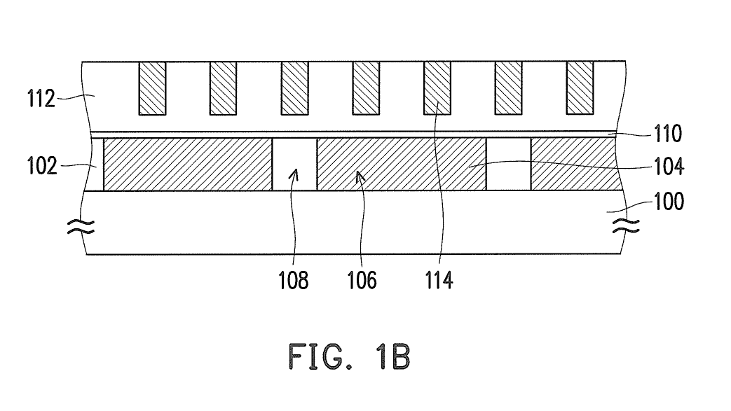

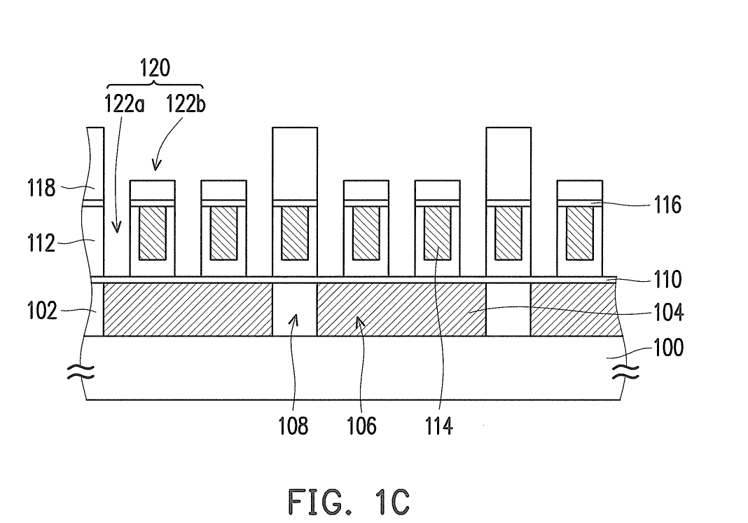

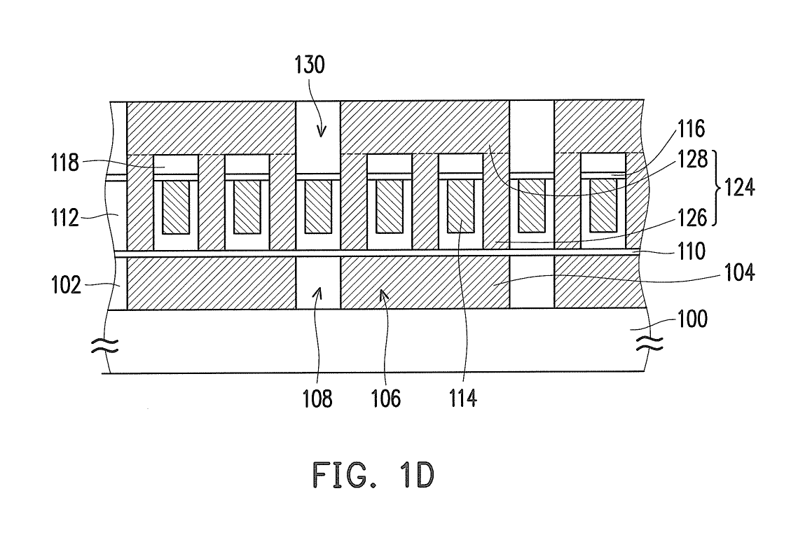

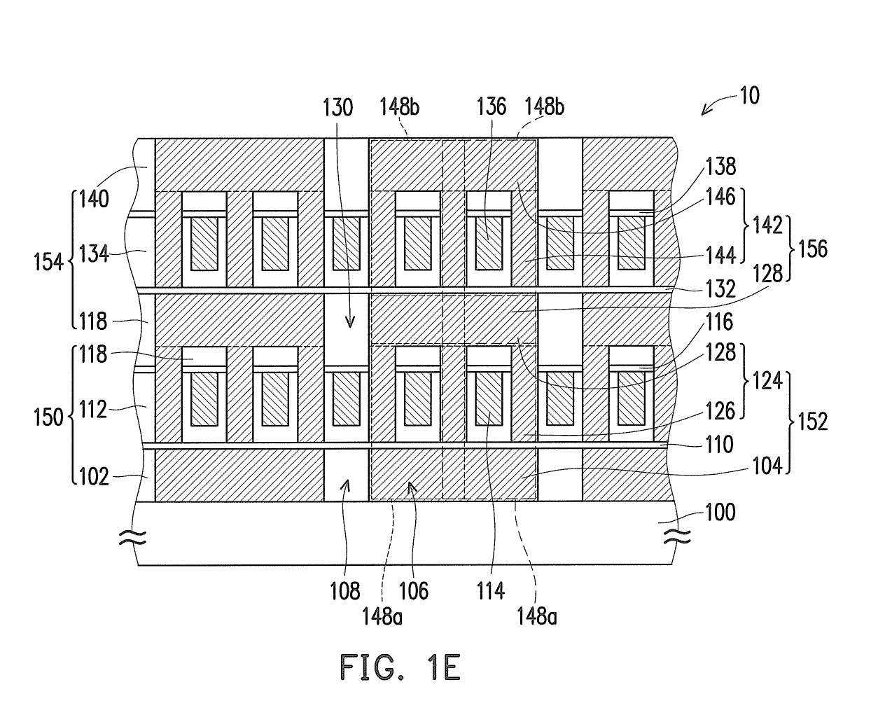

FIG. 1A to FIG. 1E are cross-sectional views of a manufacturing process of a capacitor structure according to an embodiment of the invention.

Referring to FIG. 1A, a dielectric layer 102 is formed on a substrate 100. The substrate 100 is not particularly limited in the invention. For instance, the substrate 100 may be any semiconductor substrate, or may be a substrate on which other layers are disposed. A material of the dielectric layer 102 is, for example, a low K material or silicon oxide. The low K material is, for example, SiOC. A method of forming the dielectric layer 102 is, for example, a chemical vapor deposition process.

A metal layer 104 is formed in the dielectric layer 102. A material of the metal layer 104 is, for example, copper, aluminum or tungsten. A method of forming the metal layer 104 is, for example, a damascene method. The metal layer 104 and the substrate 100 could be separated by a dielectric layer (not shown). For instance, the method of forming the metal layer 104 may include the following steps. A patterning process is performed on the dielectric layer 102, and an opening 106 is formed in the dielectric layer 102. A metal material layer (not marked) filling the opening 106 is formed. A method of forming the metal material layer is, for example, an electroplating method, a physical vapor deposition process or a chemical vapor deposition process. The metal material layer located outside the opening 106 is removed, and the metal layer 104 is formed in the dielectric layer 102. A method of removing the metal material layer outside the opening 106 is, for example, a chemical mechanical polishing method. In the present embodiment, although the metal layer 104 is formed by using the damascene method as described above, the method of forming the metal layer 104 of the invention is not limited thereto.

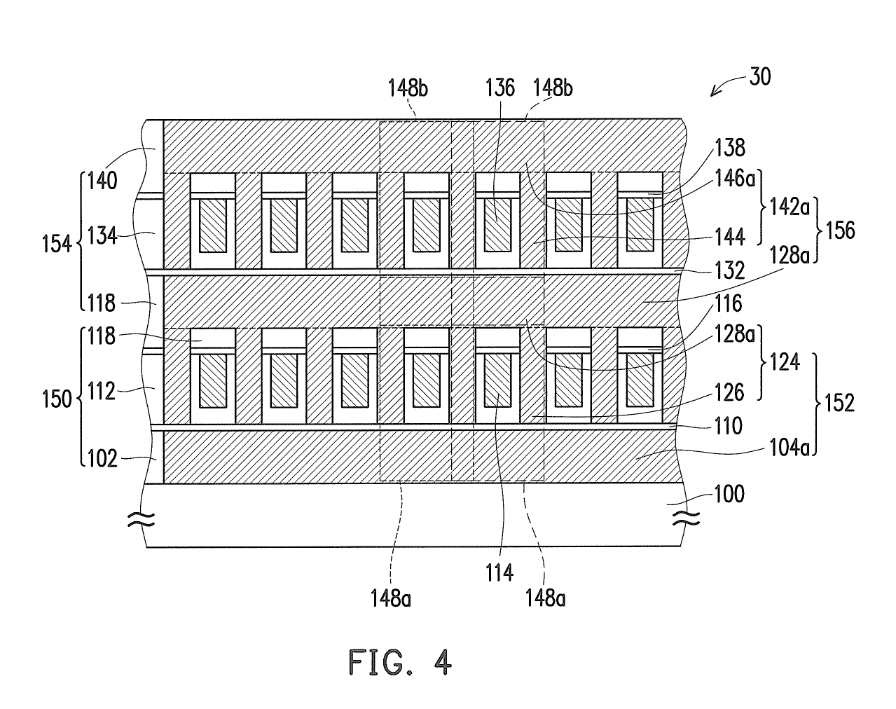

In addition, based on a pattern design of the opening 106, a shape of the metal layer 104 may be decided, and thus it is possible that at least one opening 108 is included in the metal layer 104. In the present embodiment, the opening 108 is filled by, for example, the dielectric layer 102. An area of the opening 108 occupies 20% to 80% of a total area of the metal layer 104 and the opening 108, for example. Within above-said proportional range of the area of the opening 108, a degree of decreasing a capacitance by the opening 108 is not significant (e.g., the degree of decreasing the capacitance may be controlled to less than 5%). Further, when the opening 108 is included in the metal layer 104, dishings produced on the metal layer 104 due to the chemical mechanical polishing method may be avoided. In another embodiment, it is also possible that the opening 108 is not included in the metal layer 104 (referring to FIG. 4 in the following disclosure).

Referring to FIG. 1B, an etching stop layer 110 may be selectively formed on the dielectric layer 102. A material of the etching stop layer 110 is silicon nitride or SiCN, for example. A method of forming the etching stop layer 110 is, for example, a chemical vapor deposition process. In addition to uses in manufacturing the capacitor, the etching stop layer 110 may also be used to manufacture other semiconductor devices, such as logic devices.

A dielectric layer 112 is formed on the etching stop layer 110. A material of the dielectric layer 112 is, for example, a low K material or silicon oxide. The low K material is, for example, SiOC. A method of forming the dielectric layer 112 is, for example, a chemical vapor deposition process.

At least one inner metal layer 114 is formed in the dielectric layer 112. A material of the inner metal layer 114 is, for example, copper, aluminum or tungsten. A method of forming the inner metal layer 114 is, for example, a damascene method. The method of forming the inner metal layer 114 may adopt a forming method similar to that of the metal layer 104, and a difference between the two methods lies where the formed patterns are different. Therefore, the method of forming the inner metal layer 114 is omitted hereinafter.

Referring to FIG. 1C, an etching stop layer 116 may be selectively formed on the dielectric layer 112. A material of the etching stop layer 116 is silicon nitride or SiCN, for example. A method of forming the etching stop layer 116 is, for example, a chemical vapor deposition process. In addition to uses in manufacturing the capacitor, the etching stop layer 116 may also be used to manufacture other semiconductor devices, such as logic devices.

A dielectric layer 118 is formed on the etching stop layer 116. A material of the dielectric layer 118 is, for example, a low K material or silicon oxide. The low K material is, for example, SiOC. A method of forming the dielectric layer 118 is, for example, a chemical vapor deposition process.

An opening structure 120 is formed in the dielectric layer 118, the etching stop layer 116 and the dielectric layer 112, and the opening structure 120 includes openings 122a and an opening 122b. The openings 122a are disposed at two sides of the inner metal layer 114, and bottom portions of the openings 122a are located equal to or below a lower surface of the inner metal layer 114. The opening 122b is disposed over the inner metal layer 114, and connects to the openings 122a. The opening structure 120 is a dual damascene opening, for example. A method of forming the opening structure 120 includes utilization of a lithography process and an etching process.

Referring to FIG. 1D, a metal structure 124 is formed in the dielectric layer 118, the etching stop layer 116 and the dielectric layer 112. A material of the metal structure 124 is, for example, copper, aluminum or tungsten. A method of forming the metal structure 124 includes, for example, forming a metal material layer (not marked) filling the opening structure 120 first, and then removing the metal material layer located outside the opening structure 120. A method of forming the metal material layer is, for example, an electroplating method, a physical vapor deposition process or a chemical vapor deposition process. A method of removing the metal material layer outside the opening structure 120 is, for example, a chemical mechanical polishing method. In the present embodiment, although the metal structure 124 is formed by using the dual damascene method as described above, the method of forming the metal structure 124 of the invention is not limited thereto.

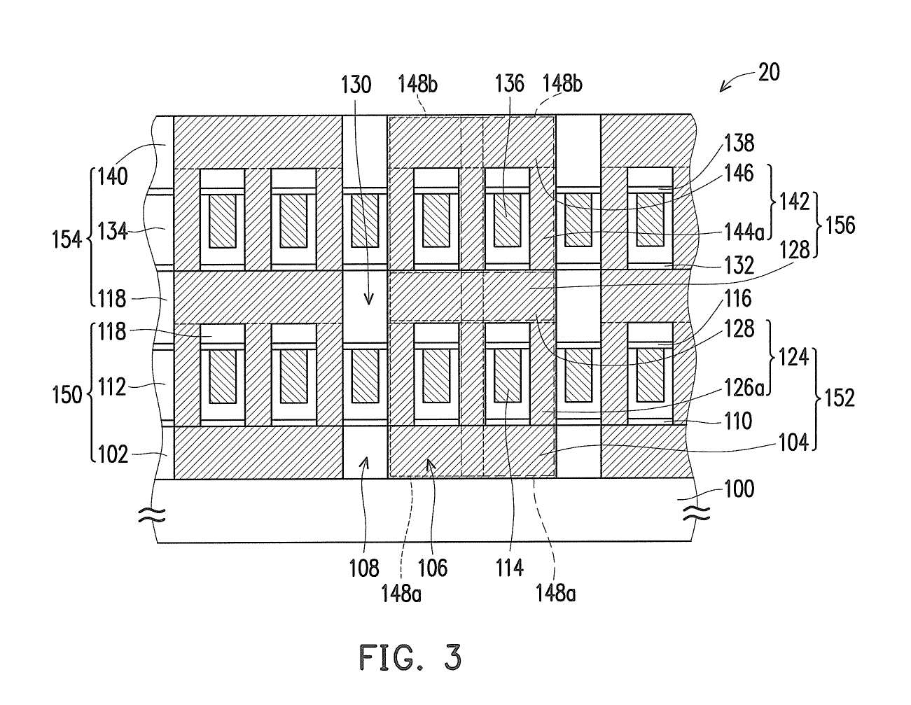

In addition, the metal layer 124 includes metal layers 126 and a metal layer 128. The metal layers 126 are disposed at the two sides of the inner metal layer 114, and lower surfaces of the metal layers 126 are located equal to or below the lower surface of the inner metal layer 114. The metal layer 128 is disposed over the inner metal layer 114 and connects to the metal layers 126. In the present embodiment, after extending to the etching stop layer 110, the bottom portions of the openings 122a stop to extend further below, and thus it is possible that the metal layers 126 are not connected to the metal layer 104. In another embodiment, the openings 122a may also penetrate the etching stop layer 110 to expose the metal layer 104, and thus it is possible that the metal layers 126a are connected to the metal layer 104 (referring to FIG. 3 in the following disclosure).

In addition, based on a pattern design of the opening 122b, a shape of the metal layer 128 may be decided, and thus it is possible that at least one opening 130 is included in the metal layer 128. In the present embodiment, the opening 130 is filled by, for example, the dielectric layer 118. An area of the opening 130 occupies 20% to 80% of a total area of the metal layer 128 and the opening 130, for example. Within above-said proportional range of the area of the opening 130, a degree of decreasing a capacitance by the opening 108 is not significant (e.g., the degree of decreasing the capacitance may be controlled to less than 5%). Further, when the opening 130 is included in the metal layer 128, dishings produced on the metal layer 128 due to the chemical mechanical polishing method may be avoided. In another embodiment, it is also possible that the opening 130 is not included in the metal layer 128 (referring to FIG. 4 in the following disclosure).

Referring to FIG. 1E, the steps of forming the etching stop layer 110, the dielectric layer 112, the inner metal layer 114, the etching stop layer 116, the dielectric layer 118 and the metal structure 124 may be performed selectively and repeatedly to form an etching stop layer 132, a dielectric layer 134, an inner metal layer 136, an etching stop layer 138, a dielectric layer 140 and a metal structure 142, so as to form a stack type capacitor structure. The metal structure 142 includes metal layers 144 and a metal layer 146. Furthermore, a person of ordinary skill in the art may decide a number of times for repeating above-said steps according to a design requirement of the capacitor structure.

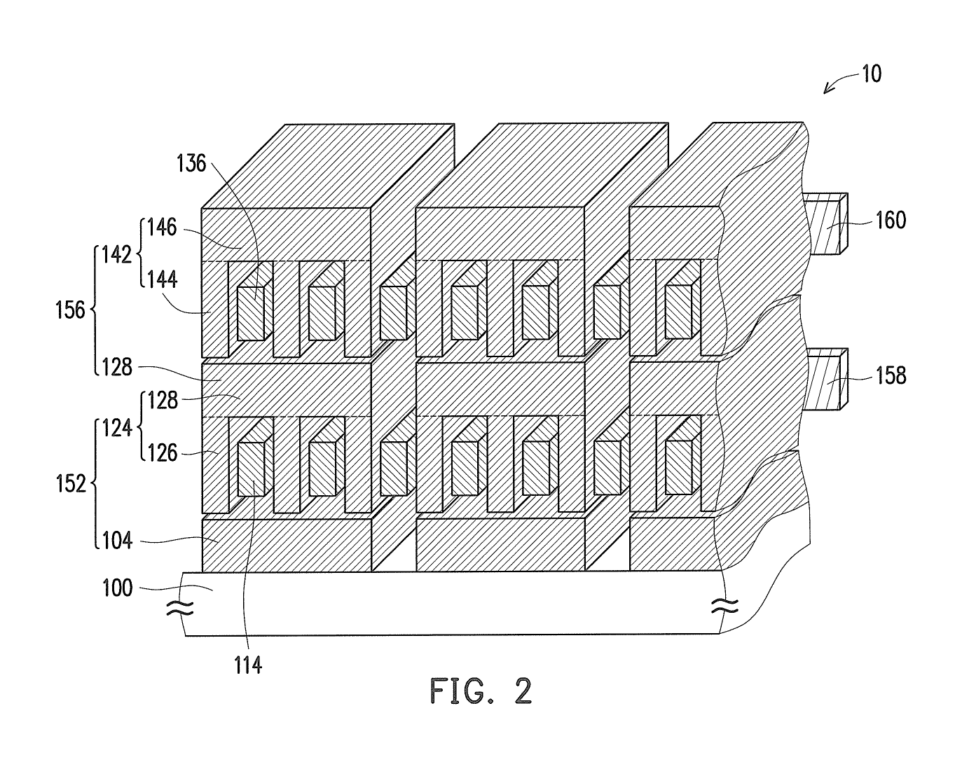

Hereinafter, a capacitor structure according to an embodiment of the invention is described by reference with FIG. 1E and FIG. 2. FIG. 2 is a three dimensional view of the metal layers in the capacitor structure of FIG. 1E. For clarity of the description, the dielectric layers and the etching stop layers are not illustrated in FIG. 2.

Referring to FIG. 1E and FIG. 2 together, a capacitor structure 10 includes capacitor units 148a and 148b. In the present embodiment, the capacitor structure 10 is illustrated to include a plurality of capacitor units 148a and a plurality of capacitor units 148b for example. However, it falls within the scope of the invention for which protection is sought, as long as the capacitor structure 10 includes at least one capacitor unit 148a or at least one capacitor unit 148b.

The capacitor unit 148a includes a dielectric layer 150, the inner metal layer 114 and an outer metal layer 152. In the present embodiment, the dielectric layer 150 may include the dielectric layer 102, the dielectric layer 112 and the dielectric layer 118. The inner metal layer 114 is disposed in the dielectric layer 150. The outer metal layer 152 is disposed in the dielectric layer 150 and surrounds the inner metal layer 114. The outer metal layer 152 includes the metal layer 104, two metal layers 126 and the metal layer 128. The metal layer 104 is disposed under the inner metal layer 114. The metal layers 126 are disposed at the two sides of the inner metal layer 114, and the lower surfaces of the metal layers 126 are located equal to or below the lower surface of the inner metal layer 114. In this embodiment, it is described by using the example in which the metal layers 126 are not connected to the metal layer 104. The metal layer 128 is disposed over the inner metal layer 114 and connects to the metal layers 126. The metal layer 104, the metal layers 126 and the metal layer 128 may be electrically connected to one another by, for example, an interconnect structure (not illustrated). The capacitor unit 148a may further include at least one of the etching stop layer 110 and the etching stop layer 116. The etching stop layer 110 is disposed between the metal layer 104 and the inner metal layer 114. The etching stop layer 116 is disposed between the inner metal layer 114 and the metal layer 128.

The capacitor unit 148b includes a dielectric layer 154, the inner metal layer 136 and an outer metal layer 156. The dielectric layer 154 may include the dielectric layer 118, the dielectric layer 134 and the dielectric layer 140. The outer metal layer 156 includes the metal layer 128, the metal layers 144 and the metal layer 146. The capacitor unit 148b may further include at least one of the etching stop layer 132 and the etching stop layer 138. Since a structure of the capacitor unit 148b is similar to that of the capacitor unit 148a, disposition relation of each element in the capacitor unit 148b is not repeated hereinafter. In addition, the material, the forming method and the effect of each element in the capacitor unit 148a and the capacitor unit 148b have been described in detail in the foregoing embodiments, and thus related descriptions are not repeated hereinafter.

In view of the capacitor structure 10, it can be known that, when numbers of the capacitor units 148a and the capacitor units 148b are plural, two horizontally-adjacent capacitor units 148a may collectively use the metal layer 126 located therebetween and collectively use the metal layer 104 and the metal layer 128. The horizontally-adjacent capacitor units 148b may collectively use the metal layer 144 located therebetween and collectively use the metal layer 128 and the metal layer 146. Among vertically-adjacent capacitor units 148a and 148b, the capacitor unit 148a at below and the capacitor unit 148b at above may collectively use the metal layer 128 located therebetween.

In addition, when numbers of the capacitor units 148a and the capacitor units 148b are plural, the metal layers 104, the metal layers 126, the metal layers 128, the metal layers 144 and the metal layers 146 (which are belonging to the outer metal layers 152 and 156) may be electrically connected to one another, and the inner metal layers 114 and the inner metal layers 136 may be electrically connected to one another by, for example, an interconnect structure (not illustrated). For instance, the inner metal layers 114 may be electrically connected to one another through a wire 158, and the inner metal layers 136 may be electrically connected to one another through a wire 160 (referring to FIG. 2).

Based on the foregoing embodiments, it can be known that, because the outer metal layers 152 and 156 respectively surround the inner metal layers 114 and 136 in the capacitor structure 10, the capacitance of the capacitor structure 10 may be effectively increased. In addition, because the method of manufacturing the capacitor structure 10 according to the foregoing embodiment can be easily integrated into the existing process, the capacitor structure can be easily manufactured without increasing complexity of the process.

FIG. 3 is a cross-sectional view of a capacitor structure according to another embodiment of the invention.

Referring to FIG. 1E and FIG. 3 together, the only difference between a capacitor structure 20 of FIG. 3 and the capacitor structure 10 of FIG. 1E is that, in the capacitor structure 20, a metal layer 126a penetrates the etching stop layer 110 to be connected to the metal layer 104. A metal layer 144a penetrates the etching stop layer 132 to be connected to the metal layer 128. Further, the materials, the disposition relations, the forming methods and the effects of other elements in the capacitor structure 20 are similar to those of the elements in the capacitor structure 10, and thus related descriptions are not repeated hereinafter.

FIG. 4 is a cross-sectional view of a capacitor structure according to another embodiment of the invention.

Referring to FIG. 1E and FIG. 4 together, the only difference between a capacitor structure 30 of FIG. 3 and the capacitor structure 10 of FIG. 1E is that, in the capacitor structure 30, the opening is not included in metal layers 104a, 128a and 146a. Further, the materials, the disposition relations, the forming methods and the effects of other elements in the capacitor structure 30 are similar to those of the elements in the capacitor structure 10, and thus related descriptions are not repeated hereinafter. In another embodiment, the metal layers 126 and 144 in the capacitor structure 30 may also be connected to the metal layers 104a and 128a respectively. Namely, a disposition similar to that of the metal layers 126a and 144a in the capacitor structure 20 of FIG. 3 may also be adopted. Further, the materials, the disposition relations, the forming methods and the effects of other elements in the capacitor structure 30 are similar to those of the elements in the capacitor structure 10, and thus related descriptions are not repeated hereinafter.

In summary, the foregoing embodiments at least have the following advantages. Because the outer metal layer surrounds the inner metal layer in the capacitor structure in the foregoing embodiments, the capacitor structure may have higher capacitance. In addition, because the method of manufacturing the capacitor structure according to the foregoing embodiment can be easily integrated into the existing process, the capacitor structure can be easily manufactured without increasing complexity of the process.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A capacitor structure, comprising at least one capacitor unit, and the at least one capacitor unit comprising:
a dielectric layer;
an inner metal layer, disposed in the dielectric layer; and
an outer metal layer, disposed in the dielectric layer, and surrounding the inner metal layer, wherein the outer metal layer comprises:
a first metal layer, disposed under the inner metal layer;
two second metal layers, disposed at two sides of the inner metal layer, and lower surfaces of the second metal layers being located equal to or below a lower surface of the inner metal layer; and
a third metal layer, disposed over the inner metal layer, and connecting to the second metal layers.

2. The capacitor structure of claim 1, wherein the second metal layers are not connected to the first metal layer.

3. The capacitor structure of claim 1, wherein the second metal layers are connected to the first metal layer.

4. The capacitor structure of claim 1, wherein the first metal layer, the second metal layers, and the third metal layer are electrically connected to one another.

5. The capacitor structure of claim 1, wherein when a number of the at least one capacitor unit is plural, the first metal layers, the second metal layers, and the third metal layers are electrically connected to one another, and the inner metal layers are electrically connected to one another.

6. The capacitor structure of claim 1, wherein when a number of the at least one capacitor unit is plural, two horizontally-adjacent capacitor units collectively use the second metal layer located therebetween and collectively use the first metal layer and the third metal layer, and among vertically-adjacent capacitor units, the third metal layer of the capacitor unit at below is the first metal layer of the capacitor unit at above.

7. The capacitor structure of claim 1, wherein at least one opening is included in the first metal layer.

8. The capacitor structure of claim 1, wherein at least one opening is included in the third metal layer.

9. The capacitor structure of claim 1, further comprising a first etching stop layer, disposed between the first metal layer and the inner metal layer.

10. The capacitor structure of claim 1, further comprising a second etching stop layer, disposed between the inner metal layer and the third metal layer.

11. A method of manufacturing a capacitor structure, comprising:
forming a first dielectric layer on a substrate;
forming a first metal layer in the first dielectric layer;
forming a second dielectric layer on the first dielectric layer;
forming at least one inner metal layer in the second dielectric layer;
forming a third dielectric layer on the second dielectric layer; and
forming a metal structure in the third dielectric layer and the second dielectric layer, and the metal structure comprising:
a plurality of second metal layers, disposed at two sides of the at least one inner metal layer, and lower surfaces of the second metal layers being located equal to or below a lower surface of the at least one inner metal layer; and
a third metal layer, disposed over the at least one inner metal layer, and connecting to the second metal layers.

12. The method of manufacturing the capacitor structure of claim 11, wherein a method of forming the metal structure comprises a dual damascene method.

13. The method of manufacturing the capacitor structure of claim 11, wherein a method of forming the metal structure comprises:
forming an opening structure in the third dielectric layer and the second dielectric layer, and the opening structure comprising:
a plurality of first openings, disposed at the two sides of the at least one inner metal layer, and bottom portions of the first openings being located equal to or below the lower surface of the at least one inner metal layer; and
a second opening, disposed over the at least one inner metal layer, and connecting to the first openings;
forming a metal material layer filling the opening structure; and
removing the metal material layer located outside the opening structure.

14. The method of manufacturing the capacitor structure of claim 11, wherein the second metal layers are not connected to the first metal layer.

15. The method of manufacturing the capacitor structure of claim 11, wherein the second metal layers are connected to the first metal layer.

16. The method of manufacturing the capacitor structure of claim 11, wherein at least one opening is included in the first metal layer.

17. The method of manufacturing the capacitor structure of claim 11, wherein at least one opening is included in the third metal layer.

18. The method of manufacturing the capacitor structure of claim 11, further comprising forming a first etching stop layer between the first dielectric layer and the second dielectric layer.

19. The method of manufacturing the capacitor structure of claim 11, further comprising forming a second etching stop layer between the second dielectric layer and the third dielectric layer.

20. The method of manufacturing the capacitor structure of claim 11, further comprising repeatedly performing the steps of forming the second dielectric layer, the at least one inner metal layer, the third dielectric layer and the metal structure, so as to form a stack type capacitor structure.
